(19) United States
(12) Patent Application Publication
(10) Pub. No.: US 2007/0101218 A1
(43) Pub. Date: May 3, 2007

(54) Shift register system and method for driving a shift register system

(75) Inventors: Chien-Chou Chen, Miao-Li (TW); Sz-Hsiao Chen, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/545,984

(22) Filed: Oct. 10, 2006

(30) Foreign Application Priority Data
Oct. 7, 2005 (TW) 94135064

(51) Int. Cl. G01R 31/28

(52) U.S. Cl. 714/724

(57) ABSTRACT

An exemplary shift register system (200) includes a counter (270), a shift register (210), a level shifter (220), and a plurality of switches (231-234). The counter includes a signal receiving pin connecting to a first external circuit, a pulse output pin, and a number of signal output pins. The shift register includes sixty-four register units therein, sixty-four output pins, a start pin connected to the pulse output pin of the counter, a controlling pin connected to the signal receiving pin of the counter. The level shifter includes sixty-four input pins connected to the sixty-four output pins of the shift register, and sixty-four output pins. Each switch includes sixty-four input pins connected to the output pins of the level shift through a bus line (228), sixty-four output pins that are for connection to a second external circuit, and an enabling pin connected to a respective one of the signal output pins of the counter.

### FIELD OF THE INVENTION

The present invention relates to shift register systems; and more particularly to a shift register system typically used in a liquid crystal display (LCD), and a method for driving a shift register system.

### GENERAL BACKGROUND

An LCD device has the advantages of portability, low power consumption, and low radiation, and has been widely used in various portable information products such as notebooks, personal digital assistants (PDAs), video cameras and the like. Furthermore, the LCD device is considered by many to have the potential to completely replace CRT (cathode ray tube) monitors and televisions.

FIG. 6 is an abbreviated diagram including circuitry of a typical active matrix LCD. The active matrix LCD 100 includes a display panel 107, a data driving circuit 120, a gate driving circuit 110, and a timing control circuit 130. The display panel 107 includes a first substrate (not shown), a second substrate (not shown) arranged in a position facing the first substrate, and a liquid crystal layer (not shown) sandwiched between the first substrate and the second substrate.

The first substrate includes a number n (where n is a natural number) of gate lines 101 that are parallel to each other and that each extend along a first direction, and a number m (where m is also a natural number) of data lines 102 that are parallel to each other and that each extend along a second direction orthogonal to the first direction. The first substrate also includes a plurality of thin film transistors (TFTs) 106 that function as switching elements. The first substrate further includes a plurality of pixel electrodes 103 formed on a surface thereof facing the second substrate. Each TFT 106 is provided in the vicinity of a respective point of intersection of the gate lines 101 and the data lines 102.

Each TFT 106 includes a gate electrode, a source electrode, and a drain electrode. The gate electrode of each TFT 106 is connected to the corresponding gate line 101. The source electrode of each TFT 106 is connected to the corresponding data line 102. The drain electrode of each TFT 106 is connected to a corresponding pixel electrode 103.

The second substrate includes a plurality of common electrodes 105 opposite to the pixel electrodes 103. In particular, the common electrodes 105 are formed on a surface of the second substrate facing the first substrate, and are made from a transparent material such as ITO (Indium-Tin Oxide) or the like. A pixel electrode 103, a common electrode 105 facing the pixel electrode 103, and liquid crystal molecules of the liquid crystal layer sandwiched between the two electrodes 103, 105 cooperatively define a single pixel unit.

The gate driving circuit 110 includes a first shift register 111 for receiving scanning signals, a level shifter 112 for transforming the scanning signals to a plurality of voltages, and a first output circuit 113 connected to the gate lines 101.

The data driving circuit 120 includes a second shift register 121 for receiving image signals, a sampler 122 for transforming the image signals to a plurality of voltages, and a second output circuit 123 connected to the data lines 102. The first and second shift registers 111, 121 respectively used in the gate driving circuit 110 and the data driving circuit 120 are integrated circuits (ICs).

Because the first shift register 111 has a plurality of output pins for driving the gate lines 101, the first shift register 111 must have a same number of register units therewithin. In other words, the number of output pins of the first shift register 111 must be the same as the number of register units inside the first shift register 111. This means that different first shift registers 111 need to be manufactured for different kinds of active matrix LCDs 100 that have different numbers of gate lines 101. This reduces a manufacturer's flexibility and may in effect add to costs.

It is desired to provide a shift register system which overcomes the above-described deficiencies.

### SUMMARY

In a preferred embodiment, a shift register system includes a counter, a shift register, a level shifter, and a plurality of switches. The counter includes a signal receiving pin connecting to a first external circuit, a pulse output pin, and a number of signal output pins. The shift register includes sixty-four register units therein, sixty-four output pins, a start pin connected to the pulse output pin of the counter, a controlling pin connected to the signal receiving pin of the counter. The level shifter includes sixty-four input pins connected to the sixty-four output pins of the shift register, and sixty-four output pins. Each switch includes sixty-four input pins connected to the output pins of the level shift through a bus line, sixty-four output pins that are for connection to a second external circuit, and an enabling pin connected to a respective one of the signal output pins of the counter. An exemplary method for driving the shift register system is also provided.

Other advantages and novel features will become more apparent from the following detailed description when taken in conjunction with the accompanying drawings, in which:

### BRIEF DESCRIPTION OF THE DRAWINGS

FIG. 1 is an abbreviated diagram including circuitry of a shift register system in accordance with a first embodiment of the present invention;

FIG. 2 is an abbreviated timing chart of signals transmitted in the shift register system of FIG. 1;

FIG. 3 is an abbreviated diagram including circuitry of a shift register system in accordance with a second embodiment of the present invention;

FIG. 4 is an abbreviated timing chart of signals transmitted in the shift register system of FIG. 3;

FIG. 5 is an abbreviated diagram including circuitry of an liquid crystal display using the shift register system of FIG. 1 or FIG. 3; and

FIG. 6 is an abbreviated diagram including circuitry of a conventional active matrix LCD.

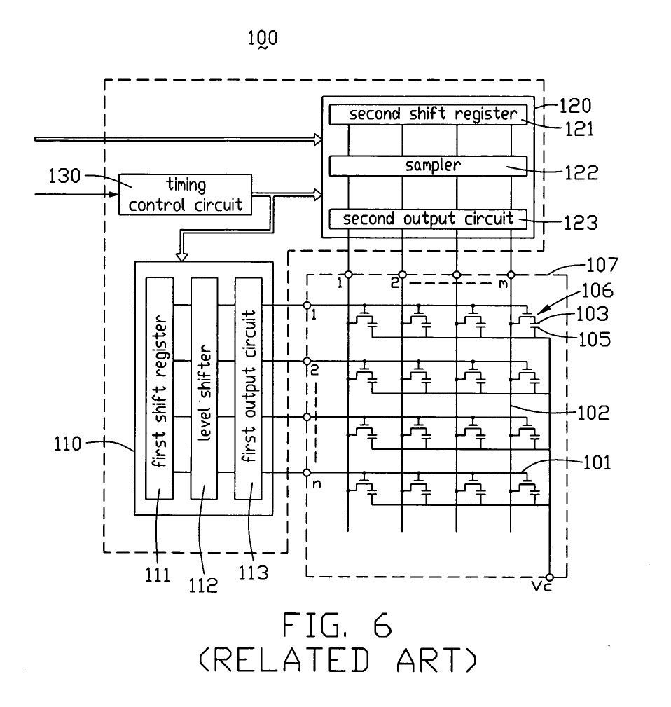

### DETAILED DESCRIPTION OF PREFERRED EMBODIMENTS

Reference will now be made to the drawings to describe preferred and exemplary embodiments of the present invention in detail.

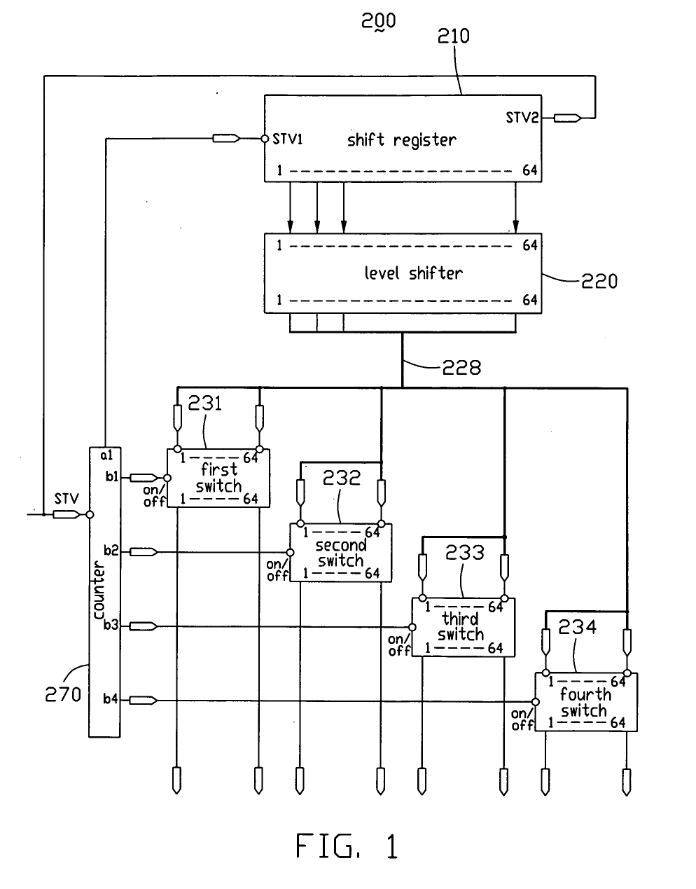

FIG. 1 is an abbreviated diagram including circuitry of a shift register system in accordance with a first embodiment of the present invention. The shift register system 200 includes a counter 270, a shift register 210, a level shifter 220, a first switch 231, a second switch 232, a third switch 233, and a fourth switch 234.

The counter 270 includes a signal receiving pin STV which is connected to a first external circuit (not shown), a pulse output pin a1, and four signal output pins b1, b2, b3, b4.

The shift register 210 includes sixty-four register units (not shown) integrated therein, sixty-four output pins, a start pin STV 1 which is connected to the pulse output pin al of the counter 270, and a controlling pin STV2 connected to the signal receiving pin STV of the counter 270.

The level shifter 220 includes sixty-four output pins, and sixty-four input pins that are connected to the output pins of the shift register 210 respectively.

Each of the switches 231, 232, 233, 234 includes sixty-four input pins that are connected to the output pins of the level shifter 220 through a bus line 228, sixty-four output pins that are connected to a second external circuit (not shown), and an enabling pin on/off which is connected to a respective one of the signal output pins (b1, b2, b3, b4) of the counter 270.

In particular, the enabling pin on/off of the first switch 231 is connected to the signal output pin b1 of the counter 270. The enabling pin on/off of the second switch 232 is connected to the signal output pin b2 of the counter 270. The enabling pin on/off of the third switch 233 is connected to the signal output pin b3 of the counter 270. The enabling pin on/off of the fourth switch 234 is connected to the signal output pin b4 of the counter 270. Accordingly, the shift register system 200 has two hundred and fifty-six output pins. The shift register system 200 may have an expanded number of output pins according to a desired quantity of switches used therein.

A method for driving the shift register system 200 includes the following steps: triggering the counter 270 to switch to an on state by an external start signal received from the first external circuit; transmitting a first start signal to activate the shift register 210 to be in an on state by the counter 270; transmitting a second start signal to activate a switch j (i.e., 231 or 232 or 233 in the first embodiment) to be in an on state by the counter 270; transmitting a plurality of shift signals from the output pins of the shift register 210 to the level shifter 220, transforming the shift signals to a plurality of voltages; transmitting the voltages to the switch j when the switch j is in the on state; providing the voltages to the second external circuit when the switch j is in the on state; transmitting a third start signal to activate a switch j+1 (i.e., 232 or 233 or 234 in the first embodiment) to be in an on state by the counter 270; transmitting a plurality of shift signals from the output pins of the shift register 210 to the level shifter 220; transforming the shift signals to a plurality of voltages; transmitting the voltages to the switch j+1 when the switch j+1 is in the on state; and providing the voltages to the second external circuit when the switch j+1 is in the on state.

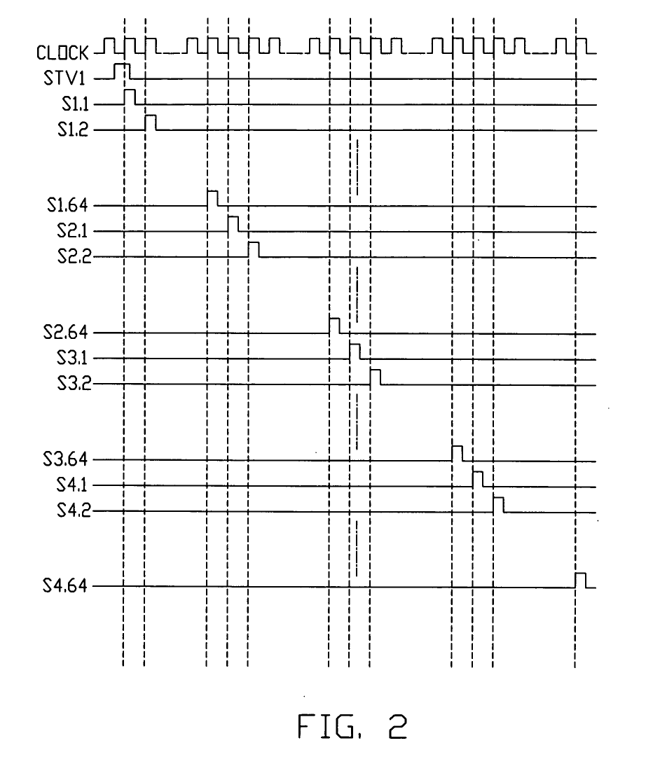

FIG. 2 is an abbreviated timing chart of signals transmitted in the shift register system 200. In operation, the signal receiving pin STV of the counter 270 receives a start pulse signal from the first external circuit, and is activated to be in an on state. Then the counter 270 provides a first start signal to the start pin STV1 of the shift register 210 and synchronously provides a second start signal to the enabling pin on/off of the first switch 231, in order to activate the shift register 210 and the first switch 231. When the shift register 210 receives the first start signal, it generates a plurality of shift signals and provides the shift signals to the level shifter 220. The level shifter 220 transforms the shift signals to a plurality of voltages, and outputs the voltages from the sixty-four output pins thereof. Because the first switch 231 is already turned on by reason of the enabling pin on/off thereof having received the second start signal, the first switch 231 receives the voltages provided by the level shifter 220, and outputs the voltages from the sixty-four output pins thereof. The voltages outputted by the first switch 231 are shown as S1.1-S1.64 in FIG. 2. At the same time, the other switches 232, 233, 234 are in an off state.

After sixty-three clock periods, the controlling pin STV2 of the shift register 210 applies a first feeding signal to the signal receiving pin STV of the counter 270. Then the counter 270 provides a third start signal to the enabling pin on/off of the second switch 232, in order to activate second switch 232. Because the second switch 232 is turned on by reason of the enabling pin on/off thereof having received the third start signal, the second switch 232 receives voltages provided by the level shifter 220, and outputs the voltages from the sixty-four output pins thereof. The voltages outputted by the second switch 232 are shown as S2.1-S2.64 in FIG. 2. At the same time, the other switches 231, 233, 234 are in an off state.

After sixty-three clock periods, the controlling pin STV2 of the shift register 210 applies a second feeding signal to the signal receiving pin STV of the counter 270. Then the counter 270 provides a fourth start signal to the enabling pin on/off of the third switch 233, in order to activate third switch 233. Because the third switch 233 is turned on by reason of the enabling pin on/off thereof having received the fourth start signal, the third switch 233 receives the voltages provided by the level shifter 220, and outputs the voltages from the sixty-four output pins thereof. The voltages outputted by the third switch 233 are shown as S3.1-S3.64 in FIG. 2. At the same time, the other switches 231, 232, 234 are in an off state.

After sixty-three clock periods, the controlling pin STV2 of the shift register 210 applies a third feeding signal to the signal receiving pin STV of the counter 270. Then the counter 270 provides a fifth start signal to the enabling pin on/off of the fourth switch 234, in order to activate fourth switch 234. Because the fourth switch 234 is turned on by reason of the enabling pin on/off thereof having received the fifth start signal, the fourth switch 234 receives the voltages provided by the level shifter 220, and outputs the voltages from the sixty-four output pins thereof. The voltages outputted by the fourth switch 234 are shown as S4.1-S4.64 in FIG. 2. At the same time, the other switches 231, 232, 233 are in an off state.

After sixty-three clock periods, the controlling pin STV2 of the shift register 210 applies a fourth feeding signal to the signal receiving pin STV of the counter 270. Then the counter 270 either applies another second start signal to the enabling pin on/off of the first switch 231 in order to activate first switch 231 once again, or stops working.

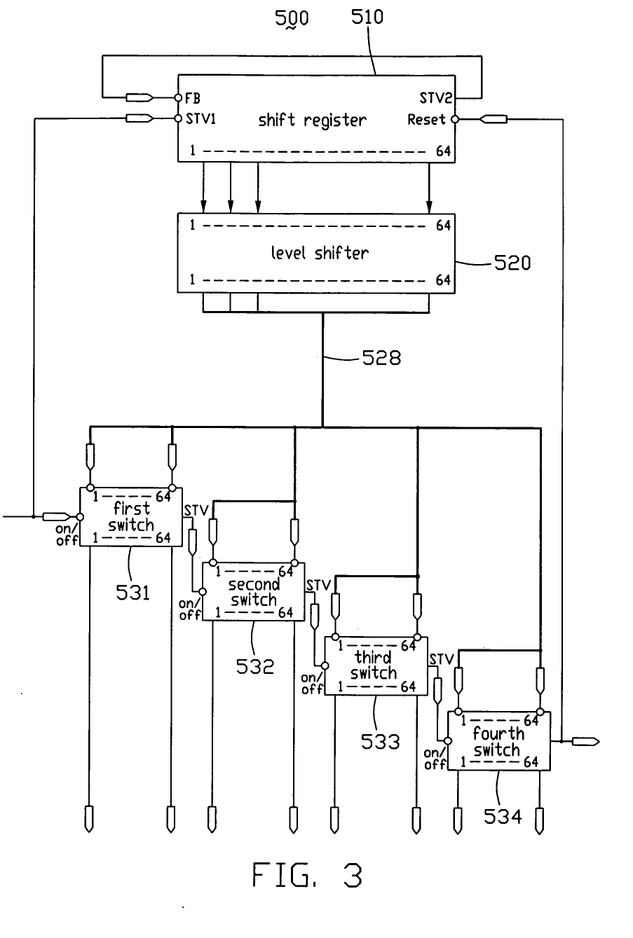

FIG. 3 is an abbreviated diagram including circuitry of a shift register system in accordance with a second embodiment of the present invention. The shift register system 500 includes a shift register 510, a level shifter 520, a first switch 531, a second switch 532, a third switch 533, and a fourth switch 534.

The shift register 510 includes sixty-four register units (not shown) integrated therein, sixty-four output pins, a start pin STV 1 for receiving an external start signal from a first external circuit (not shown), a reset pin Reset, a first controlling pin FB, and a second controlling pin STV2.

The level shifter 520 includes sixty-four output pins, and sixty-four input pins that are connected to the output pins of the shift register 510 respectively.

Each of the switches 531, 532, 533, 534 includes sixty-four input pins that are connected to the output pins of level shifter 520 through a bus line 528, sixty-four output pins, an enabling pin on/off, and a third controlling pin STV.

The switches 531, 532, 533, 534 are connected with each other in series through the respective enabling pins on/off and the respective third controlling pins STV. The enabling pin on/off of the first switch 531 is connected to the start pin STV1 of the shift register 510. The third controlling pin STV of the fourth switch 534 is connected to the reset pin Reset of the shift register 510. The output pins of the shift register 510 are connected to the input pins of the level shifter 520 respectively. The output pins of the level shifter 520 are connected to the switches 531, 532, 533, 534 by a 64-bit data bus line 528. The output pins of the switches 531, 532, 533, 534 are connected to a second external circuit (not shown). Accordingly, the shift register system 500 has two hundred and fifty-six output pins. The shift register system 500 may have an expanded number of output pins according to a desired quantity of switches used therein.

A method for driving the shift register system 500 includes the following steps: triggering the shift register 510 and a switch j (i.e., 531 or 532 or 533 in the second embodiment) to switch to an on state by an external start signal received from a first external circuit; transmitting a plurality of shift signals from the output pins of the shift register 510 to the level shifter 520; transforming the shift signals to a plurality of voltages; transmitting the voltages from the level shifter 520 to the switch j when the switch j is in the on state; providing the voltages to the second external circuit when the switch j is in the on state; triggering a switch j+1 (i.e., 532 or 533 or 534 in the second embodiment) to switch to the on state, by the switch j when the switch j has finished providing the voltages to the second external circuit; transmitting the voltages from the output pins of the shift register 510 to the level shifter 520; transforming the shift signals to a plurality of voltages; transmitting the voltages from the level shifter 520 to the switch j+1 when the switch j+1 is in the on state; and providing the voltages to the second external circuit when the switch j+1 is in the on state.

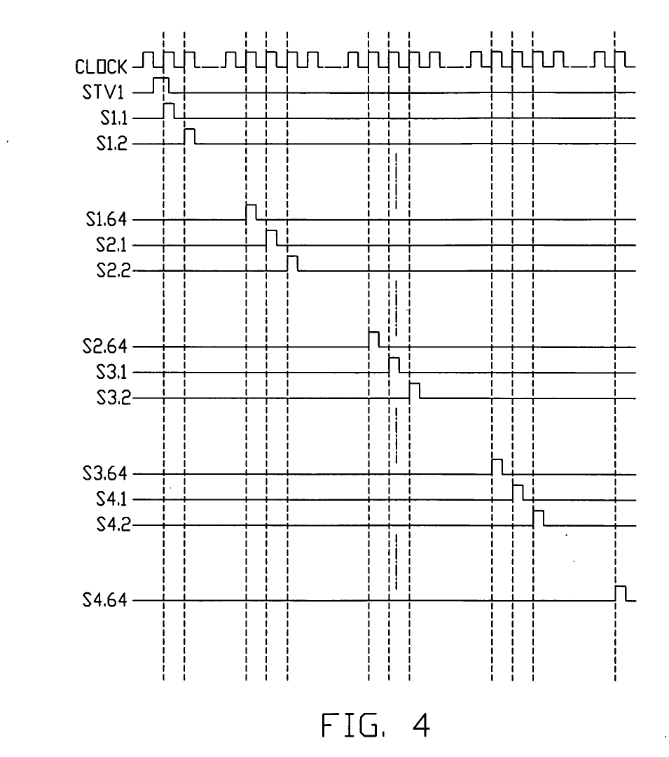

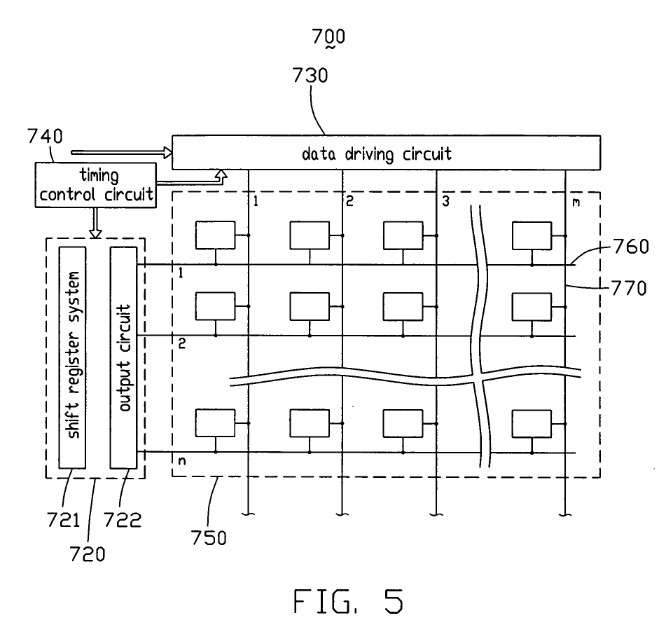

FIG. 4 is an abbreviated timing chart of signals transmitted in the shift register system 500. In operation, the enabling pin on/off of the first switch 531 and the start pin STV1 of the shift register 510 synchronously receive an external start signal from the first external circuit (not shown). When the shift register 510 receives the external start signal, it generates a plurality of shift signals and provides the shift signals to the sixty-four output pins thereof. The level shifter 520 receives shift signals, transforms the shift signals to a plurality of voltages, and provides the voltages to the sixty-four output pins thereof. Because the first switch 531 is already turned on by reason of the enabling pin on/off thereof having received the external start signal, the first switch 531 receives the voltages provided by the level shifter 520, and outputs the voltages from the sixty-four output pins thereof. The voltages outputted by the first switch 531 are shown as S1.1-S1.64 in FIG. 5. At the same time, the other switches 532, 533, 534 are in an off state.

After sixty-three clock periods, the third controlling pin STV of the first switch 531 applies a control signal to turn on the second switch 532 and turn off itself. At the same time, the second controlling pin STV2 of the shift register 510 sends a pulse to the first controlling pin FB of the shift register 510. Then the shift register 510 provides a plurality of shift signals to the sixty-four output pins thereof. The level shifter 520 receives shift signals, transforms the shift signals to a plurality of voltages, and provides the voltages to the sixty-four output pins thereof. Because the second switch 532 is already turned on by reason of the enabling pin on/off thereof having received the control signal, the second switch 532 receives the voltages provided by the level shifter 520, and outputs the voltages from the sixty-four output pins thereof. The voltages outputted by the second switch 532 are shown as S2.1-S2.64 in FIG. 5. At the same time, the other switches 531, 533, 534 are in an off state.

After sixty-three clock periods again, the third controlling pin STV of the second switch 532 applies a control signal to turn on the third switch 533 and turn off itself. At the same time, the second controlling pin STV2 of the shift register 510 sends a pulse to the first controlling pin FB of the shift register 510. Then the shift register 510 provides a plurality of shift signals to the sixty-four output pins thereof. The level shifter 520 receives shift signals, transforms the shift signals to a plurality of voltages, and provides the voltages to the sixty-four output pins thereof. Because the third switch 533 is already turned on by reason of the enabling pin on/off thereof having received the control signal, the third switch 533 receives the voltages provided by the level shifter 520, and outputs the voltages from the sixty-four output pins thereof. The voltages outputted by the third switch 533 are shown as S3.1-S3.64 in FIG. 5. At the same time, the other switches 531, 532, 534 are in an off state.

After sixty-three clock periods again, the third controlling pin STV of the third switch 533 applies a control signal to turn on the fourth switch 534 and turn off itself. At the same time, the second controlling pin STV2 of the shift register 510 sends a pulse to the controlling pin FB of the shift register 510. Then the shift register 510 provides a plurality of shift signals to the sixty-four output pins thereof. The level shifter 520 receives shift signals, transforms the shift signals to a plurality of voltages, and provides the voltages to the sixty-four output pins thereof. Because the fourth switch 534 is already turned on by reason of the enabling pin on/off thereof having received the control signal, the fourth switch 534 receives the voltages provided by the level shifter 520, and outputs the voltages from the sixty-four output pins thereof. The voltages outputted by the fourth switch 534 are shown as S4.1-S4.64 in FIG. 5. At the same time, the other switches 531, 532, 533 are in an off state.

After the fourth switch 534 has outputted the voltages from the sixty-four output pins thereof, the fourth switch 534 turns off itself. At the same time, the fourth switch 534 sends a pulse signal from the third controlling pin STV thereof to the reset pin Reset of the shift register 510. After the shift register 510 receives the pulse signal, it stops outputting the voltages.

FIG. 5 is an essential abbreviated diagram including circuitry of an exemplary liquid crystal display using the shift register system 200 or 500. The liquid crystal display 700 includes a display panel 750, a gate driving circuit 720, a data driving circuit 730, and a timing control circuit 740. The display panel 750 includes a first substrate (not shown), a second substrate (not shown), and a liquid crystal layer (not shown) sandwiched between the first and second substrates. The first substrate includes a number n (where n is a natural number) of gate lines 760 that are parallel to each other and that each extend along a first direction, and a number m (where m is also a natural number) of data lines 770 that are parallel to each other and that each extend along a second direction orthogonal to the first direction. The first substrate also includes a plurality of thin film transistors (not shown) that function as switching elements. Each TFT is provided in the vicinity of a respective point of intersection of the gate lines 760 and the data lines 770.

The gate driving circuit 720 includes a shift register system 721, for transforming the scanning signals to a plurality of voltages, and an output circuit 722 connected to the gate lines 760. The shift register system has a same configuration as that of the shift register system 200 or that of the shift register system 500.

The data driving circuit 730 includes a shift register (not shown) for receiving image signals, a sampler (not shown) for transforming the image signals to a plurality of voltages, and an output circuit (not shown) connected to the data lines 770. 1004

The above-described exemplary shift register system 200 or 500 has two hundred and fifty-six output pins. Unlike in the typical shift register used in the above-described conventional gate driving circuit 110, the shift register system 200 or 500 may have a reduced or expanded number of output pins according to a selected quantity of switches used therein.

It is to be understood, however, that even though numerous characteristics and advantages of preferred embodiments have been set out in the foregoing description, together with details of the structures and functions of the embodiments, the disclosure is illustrative only; and that changes may be made in detail, especially in matters of shape, size, and arrangement of parts within the principles of the present invention to the full extent indicated by the broad general meaning of the terms in which the appended claims are expressed.

What is claimed is:

1. A shift register system comprising:
a counter comprising a signal receiving pin configured to be connected to a first external circuit, a pulse output pin, and a plurality of signal output pins;
a shift register comprising sixty-four register units therein, sixty-four output pins, a start pin connected to the pulse output pin of the counter, and a controlling pin connected to the signal receiving pin of the counter;
a level shifter comprising sixty-four input pins connected to the sixty-four output pins of the shift register, and sixty-four output pins; and
a plurality of switches, each of the switches comprising sixty-four input pins that are connected to the output pins of the level shifter through a bus line, sixty-four output pins configured to be connected to a second external circuit, and an enabling pin connected to a respective one of the signal output pins of the counter.

2. The shift register system as claimed in claim 1, wherein the plurality of the switches is four switches.

3. A shift register system comprising:
a shift register comprising a start pin configured for receiving signals from a first external circuit, a plurality of output pins, a reset pin, a first controlling pin, and a second controlling pin;
a level shifter comprising a plurality of input pins that are connected to the output pins of the shift register, and a plurality of output pins;
a plurality of switches, each of the switches comprising a plurality of input pins that are connected to the output pins of the level shifter through a bus line, a plurality of output pins, an enabling pin, and a third controlling pin;
wherein the switches are connected with each other in series through respective of the enabling pins and controlling pins, the enabling pin of a first one of the switches is connected to the start pin of the shift register, the third controlling pin of a last one of the switches is connected to the reset pin of the shift register, and the output pins of the switches are configured to be connected to a second external circuit.

4. The shift register system as claimed in claim 3, wherein the plurality of output pins of the shift register is sixty-four output pins.

5. The shift register system as claimed in claim 3, wherein the plurality of input pins of the level shifter is sixty-four input pins, and the plurality of output pins of the level shifter is sixty-four output pins.

6. The shift register system as claimed in claim 3, wherein the plurality of switches is four switches.

7. A method for driving a shift register system, the shift register system comprising a number m (m≧1) of switches, a shift register having a number n (n≧1) of output pins, and a level shifter having a corresponding number n (n≧1) of input pins and a corresponding number n (n≧1) of output pins, the method comprising:
triggering the shift register and a first one of the switches j (1≦j≦m−1) to be in an on state;
transmitting a plurality of shift signals from the output pins of the shift register to the level shifter;
transforming the shift signals to a plurality of voltages, and transmitting the
voltages to the switch j when the switch j is in the on state;
providing the voltages to an external circuit when the switch j is in the on state;
triggering a second one of the switches j+1 (1≦j≦m−1) to be in the on state, when the switch j has finished providing the voltages to the external circuit;
transmitting the voltages from the output pins of the level shifter to the switch j+1 when the switch j+1 is in the on state; and
providing the voltages to the external circuit when the switch j+1 is in the on state.

8. The method for driving a shift register system as claimed in claim 7, wherein m is equal to four.

9. The method for driving a shift register system as claimed in claim 7, wherein n is equal to sixty-four.

10. The method for driving a shift register system as claimed in claim 7, wherein the shift register is triggered by an external start signal.

11. The method for driving a shift register system as claimed in claim 10, wherein the switch j+1 is triggered by the switch j.

12. The method for driving a shift register system as claimed in claim 7, wherein the shift register system further comprises a counter, and the method further comprises: triggering the counter to be in an on state by an external start signal received from a first external circuit.

13. The method for driving a shift register system as claimed in claim 12, wherein the shift register and the switch j are triggered by the counter.

14. The method for driving a shift register system as claimed in claim 13, wherein the switch j+1 is triggered by the counter.
